(19) United States
(12) Patent Application Publication
(10) Pub. No.: US 2025/0069856 A1
(43) Pub. Date: Feb. 27, 2025

(54) APPARATUS FOR PROCESSING SUBSTRATE

(71) Applicant: JUSUNG ENGINEERING CO., LTD., Gwangju-si, Gyeonggi-do (KR)

(72) Inventors: Chul Joo HWANG, Gwangju-si, Gyeonggi-do (KR); In Seo YOO, Gwangju-si, Gyeonggi-do (KR); Ji Hun LEE, Gwangju-si, Gyeonggi-do (KR)

(21) Appl. No.: 18/726,395

(22) PCT Filed: Dec. 27, 2022
(86) PCT No.: PCT/KR2022/021438

§ 371 Date: Jul. 2, 2024

(30) Foreign Application Priority Data
Jan. 7, 2022 (KR) 10-2022-0002973
Dec. 22, 2022 (KR) 10-2022-0181219

(51) Int. Cl. H01J 37/32

(52) U.S. Cl. CPC H01J 37/32458; H01J 37/3244; H01J 37/32568; H01J 37/32082

(57) ABSTRACT

The present inventive concept relates to an apparatus for processing a substrate, the apparatus comprising: a chamber which includes a lid on top; a first plate which is installed under the lid and in which a plurality of gas holes is formed; a second plate coupled to the first plate and including a plurality of gas holes that communicate with some of the plurality of gas holes of the first plate; and a distance adjustment part which is connected to the second plate, adjusts the distance between the lid and the first plate, and is connected to an RF power feeding line.

### TECHNICAL FIELD

The present inventive concept relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process is performed on a substrate by a substrate processing apparatus.

A substrate processing apparatus of the related art includes a substrate supporting unit which supports a substrate, a plate which is disposed on the substrate supporting unit, and a chamber where the plate is installed. The plate is coupled to the chamber so as to be disposed in the chamber.

Here, the substrate processing apparatus of the related art is supported by the chamber because the plate is coupled to only the chamber, and due to this, sag occurs in the plate due to a weight thereof. Therefore, the substrate processing apparatus of the related art has a problem where the quality of a processing process-performed substrate is degraded as a gap between the plate and a substrate supported by the substrate supporting unit is partially changed.

### DISCLOSURE

### Technical Problem

The present inventive concept is devised to solve the above-described problem and is for providing a substrate processing apparatus which may prevent the quality of a processing process-performed substrate from being degraded by the sag of a plate.

### Technical Solution

To accomplish the above-described objects, the present inventive concept may include the following elements.

A substrate processing apparatus according to the present inventive concept may include: a chamber including a lid at an upper portion thereof; a first plate installed under the lid, a plurality of gas holes being formed in the first plate; a second plate including a plurality of gas holes communicating with some of the plurality of gas holes of the first plate, the second plate being coupled to the first plate; and a gap controller connected with the second plate to control a gap between the lid and the first plate. The gap controller may be connected with an RF power feeding line.

The substrate processing apparatus according to the present inventive concept may include a feeding unit coupled to the first plate. When an RF power is applied to the first plate, the feeding unit may necessarily apply the RF power to the first plate, and the gap controller may selectively apply the RF power to the first plate.

### Advantageous Effect

According to the present inventive concept, the following effects may be realized.

The present inventive concept may be implemented so that a gap controller supports a first plate. Therefore, the present inventive concept may decrease a sag which occurs in the first plate due to a weight thereof. Accordingly, the present inventive concept may reduce the degree to which a gap between a substrate and the first plate is partially changed, thereby enhancing the quality of a substrate on which a processing process has been performed.

The present inventive concept is implemented to control a gap between a lid and the first plate by using the gap controller. Accordingly, the present inventive concept may decrease a sag occurring in the first plate, thereby enhancing the easiness of an operation for solving a sag which occurs in the first plate.

The present inventive concept may be implemented so that the gap controller is electrically connected with the first plate. Accordingly, the present inventive concept may enhance the easiness of an operation of assigning an electrical characteristic to the first plate.

### DESCRIPTION OF DRAWINGS

FIG. 1 is a schematic block diagram of a substrate processing apparatus according to the present inventive concept.

FIG. 2 is a schematic side cross-sectional view illustrating a coupling relationship between a first plate, a second plate, and a gap controller in a substrate processing apparatus according to the present inventive concept.

FIGS. 3 to 5 are schematic side cross-sectional views illustrating the enlargement of a portion A of FIG. 2 in embodiments of an adaptor included in a second plate.

FIG. 6 is a schematic side cross-sectional view illustrating a coupling relationship between a first plate, an upper plate, an upper adaptor, a lower adaptor, an upper gap controller, and a lower gap controller in a substrate processing apparatus according to the present inventive concept.

FIG. 7 is a schematic plan view of a first plate in a substrate processing apparatus according to the present inventive concept.

FIG. 8 is a schematic side cross-sectional view of an embodiment including a protrusion electrode and an opening in a substrate processing apparatus according to the present inventive concept.

FIG. 9 is a schematic side cross-sectional view of an embodiment including a feeding unit in a substrate processing apparatus according to the present inventive concept.

### [Mode for Inventive Concept]

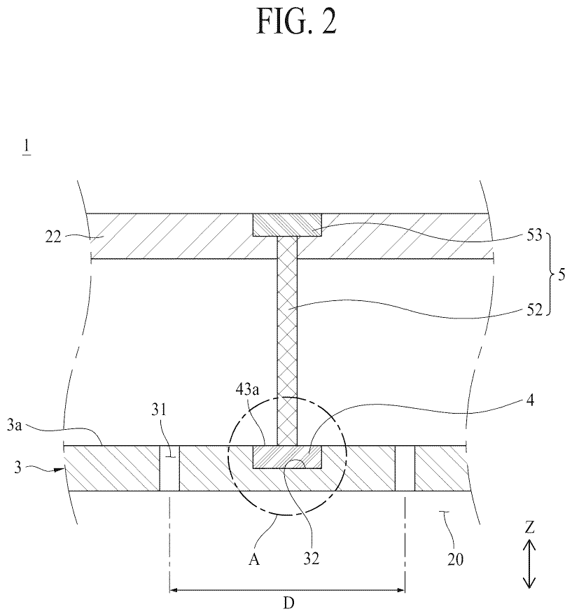

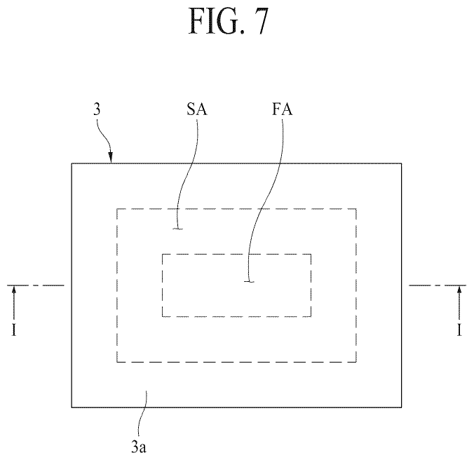

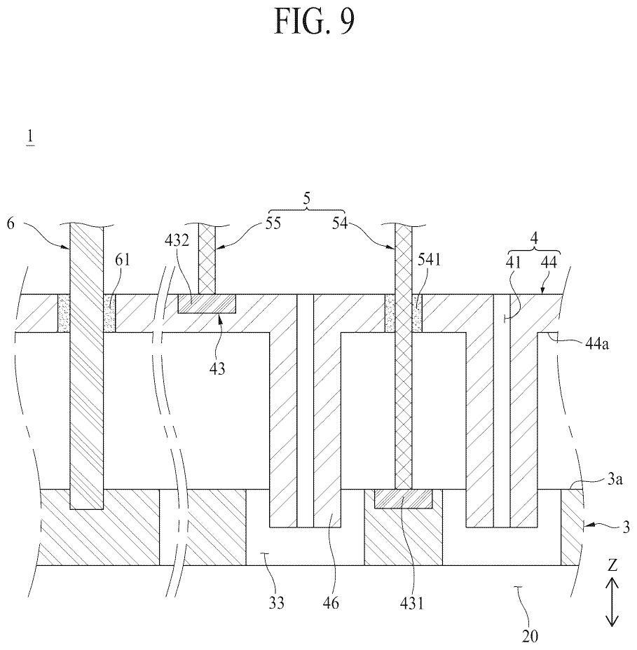

Hereinafter, an embodiment of a substrate processing apparatus according to the present inventive concept will be described in detail with reference to the accompanying drawings. FIGS. 2 to 6, 8, and 9 may be side cross-sectional views with respect to line I-I of FIG. 7. In FIG. 7, gas holes formed in a first plate and adaptors coupled to the first plate are omitted.

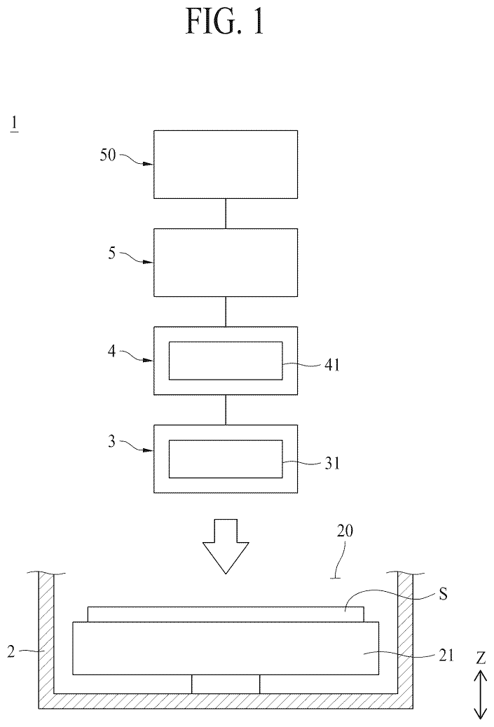

Referring to FIG. 1, a substrate processing apparatus 1 according to the present inventive concept performs a processing process on a substrate S. The substrate S may be a silicon substrate, a glass substrate, or a metal substrate. The substrate processing apparatus 1 according to the present inventive concept may perform a deposition process of depositing a thin film on the substrate S and an etching process of removing a portion of the thin film deposited on the substrate S. Hereinafter, an embodiment where the substrate processing apparatus 1 according to the present inventive concept performs the deposition process will be described, but it is obvious to those skilled in the art that an embodiment is deduced where the substrate processing apparatus 1 according to the present inventive concept performs another processing process such as the deposition process or the like.

The substrate processing apparatus 1 according to the present inventive concept may include a chamber 2, a first plate 3, a second plate 4, and a gap controller 5.

Referring to FIG. 1, the chamber 2 provides a processing space 20. In the processing space 20, a processing process such as a deposition process or an etching process may be performed on the substrate S. The processing space 20 may be disposed in the chamber 2. An exhaust port (not shown) which exhausts a gas from the processing space 20 may be coupled to the chamber 2. The first plate 3, an adaptor 43, and the gap controller 5 may be disposed in the chamber 2. A portion of the gap controller 5 may be disposed outside the chamber 2.

The substrate supporting unit 21 may be installed in the chamber 2. The substrate supporting unit 21 supports the substrate S. The substrate supporting unit 21 may support one substrate S, or may support a plurality of substrates S. When the plurality of substrates S are supported by the substrate supporting unit 21, a processing process on the plurality of substrates S may be performed at a time. The substrate supporting unit 21 may be coupled to the chamber 2. The substrate supporting unit 21 may be disposed in the chamber 2.

Referring to FIGS. 1 and 2, the first plate 3 is installed in the chamber 2. The first plate 3 may be coupled to the chamber 2 so as to be disposed in the chamber 2. The first plate 3 may be disposed to be opposite to the substrate supporting unit 21. The first plate 3 may be disposed on the substrate supporting unit 21 with respect to a vertical direction (a Z-axis direction). The vertical direction (the Z-axis direction) is an axial direction parallel to a direction in which the first plate 3 is apart from the substrate supporting unit 21. The processing space 20 may be disposed between the first plate 3 and the substrate supporting unit 21. The first plate 3 may be coupled to a lid 22. The lid 22 may be disposed to cover an upper portion of the chamber 2.

The first plate 3 may inject a gas toward the substrate supporting unit 21. To this end, a plurality of gas holes 31 [hereinafter referred to as a ‘lower gas hole 31’] may be formed in the first plate 3. A gas may pass through the lower gas holes 31 and may be injected toward the substrate supporting unit 21. The gas may be used for a processing process on the substrate S and may be supplied from a gas storage unit (not shown). Each of the lower gas holes 31 may be formed to pass through the first plate 3. The lower gas holes 31 may be arranged apart from one another.

Referring to FIGS. 1 to 4, the second plate 4 is disposed in the chamber 2. The second plate 4 may be coupled to the first plate 3. The second plate 4 may include a plurality of gas holes 41 [hereinafter referred to as an ‘upper gas hole 41’]. The upper gas holes 41 may communicate with some of the lower gas holes 31. The upper gas holes 41 may be arranged apart from one another. The gas may be injected toward the substrate S supported by the substrate supporting unit 21 through the upper gas holes 41 and the lower gas holes 31.

Referring to FIGS. 1 to 5, the gap controller 5 is connected with the second plate 4. The gap controller 5 may be connected with the first plate 3 through the second plate 4. Therefore, the gap controller 5 may support the first plate 3 through the second plate 4, and thus, may implement a supporting function on the first plate 3. In this case, one side of the gap controller 5 may be connected with the first plate 3 through the second plate 4, and the other side thereof may be supported by the lid 22. Accordingly, the gap controller 5 may support the second plate 4 by using a supporting force supported by the lid 22, and thus, may implement a supporting function on the first plate 3. Although not shown, the other side of the gap controller 5 may be supported by another structure disposed outside the chamber 2.

The gap controller 5 may be connected with a radio frequency (RF) power feeding line 50 (illustrated in FIG. 1). The RF power feeding line 50 may apply an RF power for generating plasma. The gap controller 5 may be electrically connected with the first plate 3 through the second plate 4, and thus, may implement an electrical connection function of determining an electrical characteristic of the first plate 3. In this case, one side of the gap controller 5 may be connected with the first plate 3 through the second plate 4, and the other side thereof may be connected with the RF power feeding line 50. The gap controller 5 may implement all of the supporting function and the electrical connection function.

The gap controller 5 may control a gap between the lid 22 and the first plate 3. The gap controller 5 may raise the first plate 3 through the second plate 4, and thus, may control a gap between the lid 22 and the first plate 3. As the gap between the lid 22 and the first plate 3 is controlled, a gap between the first plate 3 and the substrate S supported by the substrate supporting unit 21 may be controlled. For example, when a sag occurs in a portion of the first plate 3, the gap controller 5 may raise the second plate 4, and thus, may raise a portion, where the sag occurs, of the first plate 3 through the second plate 4. Therefore, the substrate processing apparatus 1 according to the present inventive concept may decrease the sag occurring in the first plate 3 by using the gap controller 5, and thus may reduce a gap variation between the first plate 3 and the substrate S supported by the substrate supporting unit 21. Accordingly, the substrate processing apparatus 1 according to the present inventive concept may enhance the quality of substrate S on which a processing process has been performed. Also, the substrate processing apparatus 1 according to the present inventive concept may decrease the sag occurring in the first plate by using the gap controller 5, thereby enhancing the easiness of an operation for solving the sag which occurs in the first plate 3.

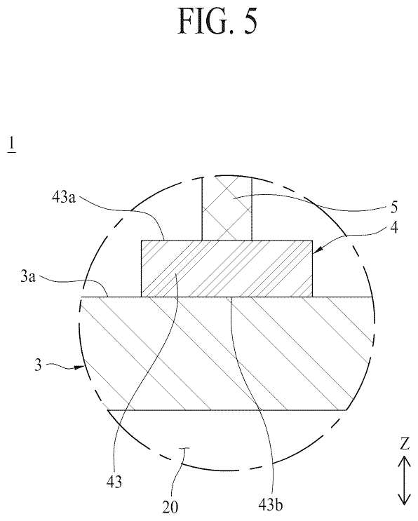

The gap controller 5 may include a coupling member 51 (illustrated in FIG. 5).

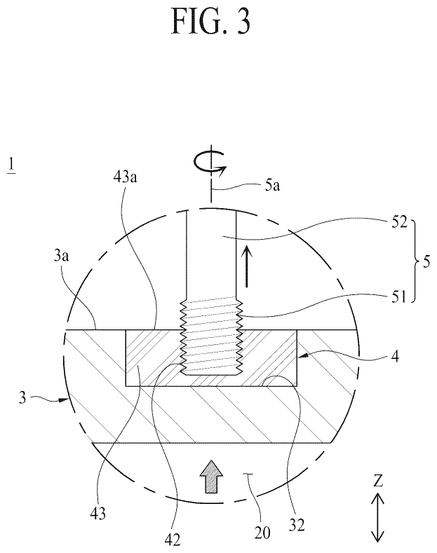

The coupling member 51 is fastened with the second plate 4 through a coupling groove 42 (illustrated in FIG. 3) formed in the second plate 4. A screw thread may be formed on an outer perimeter surface of the coupling member 51. A screw thread corresponding to the screw thread formed on the outer perimeter surface of the coupling member 51 may be formed on an inner surface of the second plate 4 facing the coupling groove 42.

The coupling member 51 may be fastened with the second plate 4 through the coupling groove 42, and thus, may raise the second plate 4. For example, when a sag occurs in a portion, fastened with the second plate 4, of the first plate 3, the coupling member 51 may rotate in a direction fastened with the second plate 4, and thus, may raise the second plate 4. As the second plate 4 is raised, the portion, fastened with the second plate 4, of the first plate 3 may be raised. Therefore, the substrate processing apparatus 1 according to the present inventive concept may decrease the sag occurring in the first plate 3 by using coupling between the coupling member 51 and the second plate 4, and thus, may reduce a gap variation between the first plate 3 and the substrate S supported by the substrate supporting unit 21. Accordingly, the substrate processing apparatus 1 according to the present inventive concept may enhance the quality of substrate S on which a processing process has been performed. Also, the substrate processing apparatus 1 according to the present inventive concept may decrease the sag occurring in the first plate by using a rotation of the gap controller 5, thereby enhancing the easiness of an operation for solving the sag which occurs in the first plate 3. The coupling member 51 may rotate as the gap controller 5 rotates about a rotational shaft 5a. The rotational shaft 5a of the gap controller 5 may be disposed in parallel in the vertical direction (the Z-axis direction).

The gap controller 5 may include a connection member 52 and a supporting member 53.

The connection member 52 is coupled to each of the coupling member 51 and the supporting member 53. The coupling member 51 and the supporting member 53 may be connected with each other through the connection member 52. The connection member 52 may be disposed between the coupling member 51 and the supporting member 53.

The supporting member 53 is coupled to the connection member 52. The supporting member 53 may be disposed to be opposite to the coupling member 51 with respect to the connection member 52. As illustrated in FIG. 2, the supporting member 53 may be supported by the lid 22. Therefore, the supporting member 53 may support the first plate 3 through the second plate 4 by using a supporting force supported by the lid 22. The supporting member 53 may be inserted into and coupled to an upper portion of the lid 22, and thus, may be supported by the lid 22. The connection member 52 may protrude in a downward direction from a lower surface of the supporting member 53. In this case, one side of the connection member 52 may be inserted into the lid 22 and coupled to the supporting member 53, and the other side thereof may be coupled to the coupling member 51 coupled to the second plate 4.

Referring to FIGS. 1 to 5, the second plate 4 may include the adaptor 43.

The adaptor 43 is coupled to the first plate 3. The gap controller 5 may be coupled to the adaptor 43. Therefore, the adaptor 43 may function as a medium which connects the gap controller 5 with the first plate 3. Accordingly, the substrate processing apparatus 1 according to the present inventive concept may realize the following effects.

First, the substrate processing apparatus 1 according to the present inventive concept may be implemented so that the gap controller 5 supports the first plate 3 through the adaptor 43. In this case, the first plate 3 may be supported by the chamber 2 and may be supported by the gap controller 5. Therefore, the substrate processing apparatus 1 according to the present inventive concept may decrease a sag which occurs in the first plate 3 due to a weight thereof. Accordingly, the substrate processing apparatus 1 according to the present inventive concept may reduce the degree to which a gap between the lid 22 and the first plate 3 is partially changed. Therefore, the substrate processing apparatus 1 according to the present inventive concept may reduce the degree to which a gap between the first plate 3 and the substrate S supported by the substrate supporting unit 21 is partially changed, thereby enhancing the quality of a substrate on which a processing process has been performed.

Second, because the gap controller 5 is connected with the first plate 3 through the adaptor 43, the substrate processing apparatus 1 according to the present inventive concept may induce the damage or breakdown of the adaptor 43 when damage or breakdown occurs in a use process or an assembly process of connecting the gap controller 5 with the first plate 3. Accordingly, the substrate processing apparatus 1 according to the present inventive concept may reduce a possibility that the first plate 3 is damaged or broken down, thereby decreasing the maintenance/repair cost. Also, the substrate processing apparatus 1 according to the present inventive concept may induce the occurrence of damage or breakdown of the adaptor 43 which is relatively easier in maintenance/repair operation than the first plate 3, thereby enhancing the easiness of a maintenance/repair operation.

Third, the substrate processing apparatus 1 according to the present inventive concept may be implemented so that the gap controller 5 is electrically connected with the first plate 3 through the adaptor 43. In this case, the adaptor 43 may electrically connect the gap controller 5 with the first plate 3. Therefore, power for generating plasma may be applied to the first plate 3 through the gap controller 5 and the adaptor 43. Accordingly, comparing with a comparative example using a separate wiring, the substrate processing apparatus 1 according to the present inventive concept may enhance the easiness of an operation of assigning an electrical characteristic to the first plate 3.

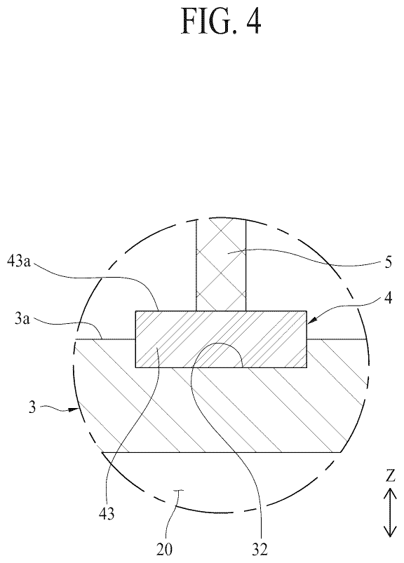

All or a portion of the adaptor 43 may be inserted into the first plate 3. As illustrated in FIGS. 2 and 3, all of the adaptor 43 may be inserted into an inserting groove 32 formed in the first plate 3. In this case, an upper surface 43a of the adaptor 43 and an upper surface 3a of the first plate 3 may be disposed at the same height. As illustrated in FIG. 4, a portion of the adaptor 43 may be inserted into the inserting groove 32 formed in the first plate 3. In this case, the upper surface 43a of the adaptor 43 may be disposed at a height which is higher than the upper surface 3a of the first plate 3. As illustrated in FIG. 5, the adaptor 43 may be coupled to the upper surface 3a of the first plate 3 to protrude upward from the upper surface 3a of the first plate 3. In this case, the inserting groove 32 is not formed in the first plate 3. A lower surface 43b of the adaptor 43 may contact the upper surface 3a of the first plate 3. The adaptor 43 may be fixedly coupled to the first plate 3 by using an adhesive. The adaptor 43 may be fixedly coupled to the first plate 3 through bonding or welding.

In a case where the adaptor 43 is provided, the coupling member 51 of the gap controller 5 may be coupled to the adaptor 43. The coupling member 51 may be coupled to the adaptor 43 through coupling. In this case, the coupling groove 42 may be formed in the adaptor 43. A screw thread corresponding to a screw thread formed on an outer perimeter surface of the coupling member 51 may be formed on an inner surface of the adaptor 43 facing the coupling groove 42. The coupling member 51 may be fastened to the adaptor 43 through the coupling groove 42, and thus, may raise the adaptor 43. For example, when a sag occurs in a portion, fastened with the adaptor 43, of the first plate 3, as illustrated in FIG. 3, the coupling member 51 may rotate in a direction fastened with the adaptor 43, and thus, may raise the adaptor 43. As the adaptor 43 is raised, the portion, fastened with the adaptor 43, of the first plate 3 may be raised. Therefore, the substrate processing apparatus 1 according to the present inventive concept may decrease the sag occurring in the first plate 3 by using coupling between the coupling member 51 and the adaptor 43, and thus, may reduce a gap variation between the first plate 3 and the substrate S supported by the substrate supporting unit 21. Also, in a case where the adaptor 43 is provided, one side of the connection member 52 of the gap controller 5 may be inserted into the lid 22 and coupled to the supporting member 53, and the other side thereof may be coupled to the coupling member 51 coupled to the adaptor 43.

In the substrate processing apparatus 1 according to the present inventive concept, each of the adaptor 43 and the gap controller 5 may be provided in plurality. In this case, the adaptors 43 may be disposed apart from one another and may be coupled to different portions of the first plate 3. The gap controllers 5 may be disposed apart from one another and may be supported by different portions of the lid 22. Therefore, the gap controllers 5 may support different portions of the first plate 3 through the adaptors 43, and thus, may decrease the degree to which a sag occurs wholly in the first plate 3. Also, the gap controllers 5 may independently rotate therebetween, and thus, may independently raise different portions of the first plate 3. Accordingly, when a sag occurs partially in the first plate 3, the gap controllers 5 may raise only a portion where a sag occurs, and thus, may enable a gap between the first plate 3 and the substrate S supported by the substrate supporting unit 21 to be uniformly maintained.

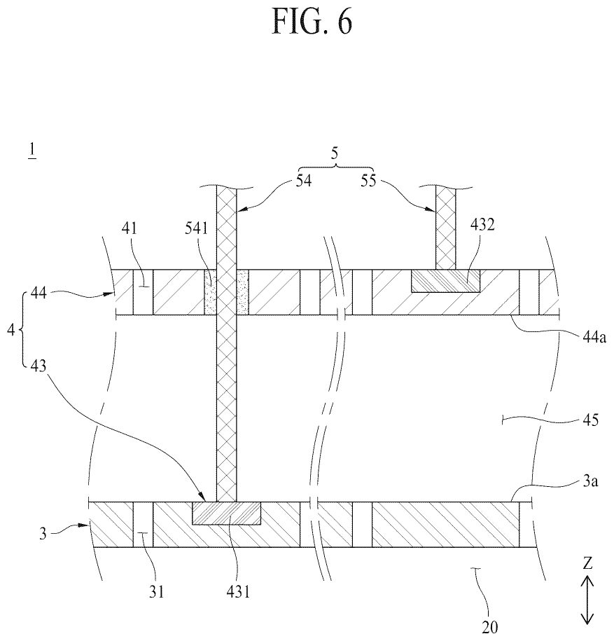

Referring to FIGS. 1 to 6, the second plate 4 may include an upper plate 44 (illustrated in FIG. 6).

The upper plate 44 is disposed on the first plate 3. The upper plate 44 and the first plate 3 may be disposed apart from each other in the vertical direction (the Z-axis direction). A separation space 45 may be disposed between the upper plate 44 and the first plate 3. The upper plate 44 and the first plate 3 may be disposed not to be electrically connected with each other through the separation space 45. Although not shown, an insulator which electrically insulates the upper plate 44 and the first plate 3 may be disposed in the separation space 45. As illustrated in FIG. 6, a lower surface 44a of the upper plate 44 may be formed to be flat. The lower surface 44a of the upper plate 44 is a surface which is disposed toward the separation space 45. In this case, an upper surface 3a of the first plate 3 may be disposed to face the separation space 45.

The upper gas holes 41 may be formed in the upper plate 44. The upper gas holes 41 may be formed at positions apart from one another to pass through the upper plate 44. A gas may pass through the upper gas hole 41 and may be injected toward the separation space 45.

In a case where the upper plate 44 and the first plate 3 are provided, the substrate processing apparatus 1 according to the present inventive concept may include a plurality of adaptors 43 and a plurality of gap controllers 5.

A lower adaptor 431 of the adaptors 43 may be coupled to the first plate 3. An upper adaptor 432 of the adaptors 43 may be coupled to the upper plate 44.

A lower gap controller 54 of the gap controllers 5 may be coupled to the lower adaptor 431 and may be connected with the first plate 3. In this case, the lower gap controller 54 may be coupled to the lower adaptor 431 at one side thereof, and the other side thereof may be coupled to the lid 22 or another structure. The other side of the lower gap controller 54 may be connected with the RF power feeding line 50, or may be grounded. The lower gap controller 54 may be inserted into the upper plate 44. In this case, an insulation member 541 may be disposed between the lower gap controller 54 and the upper plate 44. The insulation member 541 may insulate the lower gap controller 54 from the upper plate 44.

The lower gap controller 54 may be coupled to the lower adaptor 431. In this case, the lower gap controller 54 may rotate in a direction coupled to the lower adaptor 431 to raise the lower adaptor 431, and thus, may raise a portion of the first plate 3 coupled to the lower adaptor 431. Therefore, the substrate processing apparatus 1 according to the present inventive concept may decrease a sag occurring in the first plate 3 by using coupling between the lower gap controller 54 and the lower adaptor 431, and thus, may reduce a gap variation between the first plate 3 and the substrate S supported by the substrate supporting unit 21. Accordingly, the substrate processing apparatus 1 according to the present inventive concept may enhance the quality of substrate S on which a processing process has been performed. Also, the substrate processing apparatus 1 according to the present inventive concept may decrease the sag occurring in the first plate 3 on the basis of a rotation of the lower gap controller 54, thereby enhancing the easiness of an operation for solving the sag which occurs in the first plate 3. The lower gap controller 54 may include the coupling member 51, the connection member 52, and the supporting member 53 described above.

The upper gap controller 55 of the gap controllers 5 may be coupled to the upper adaptor 432 and may be connected with the upper plate 44. In this case, the upper gap controller 55 may be coupled to the upper adaptor 432 at one side thereof, and the other side thereof may be coupled to the lid 22 or another structure. The other side of the upper gap controller 55 may be connected with the RF power feeding line 50, or may be grounded. In this case, the other side of the upper gap controller 55 is connected with the RF power feeding line 50, the other side of the lower gap controller 54 may be grounded. When the other side of the upper gap controller 55 is grounded, the other side of the lower gap controller 54 may be connected with the RF power feeding line 50.

The upper gap controller 55 may be coupled to the upper adaptor 432. In this case, the upper gap controller 55 may rotate in a direction coupled to the upper adaptor 432 to raise the upper adaptor 432, and thus, may raise a portion of the upper plate 44 coupled to the upper adaptor 432. Therefore, the substrate processing apparatus 1 according to the present inventive concept may decrease a sag occurring in the upper plate 44 by using coupling between the upper gap controller 55 and the upper adaptor 432, and thus, may reduce a gap variation between the upper plate 44 and the first plate 3. Accordingly, the substrate processing apparatus 1 according to the present inventive concept may enhance the quality of substrate S on which a processing process has been performed. Also, the substrate processing apparatus 1 according to the present inventive concept may decrease the sag occurring in the upper plate 44 on the basis of a rotation of the upper gap controller 55, thereby enhancing the easiness of an operation for solving the sag which occurs in the upper plate 44. The upper gap controller 55 may include the coupling member 51, the connection member 52, and the supporting member 53 described above.

The upper gap controller 55 may be disposed more outward than the lower gap controller 54. That is, the lower gap controller 54 may be disposed more inward than the upper gap controller 55.

As illustrated in FIG. 7, the lower gap controller 54 may be coupled to the first plate 3 in a first area FA. In this case, the lower adaptor 431 may be coupled to a portion, provided in the first area FA, of the first plate 3. Therefore, the lower gap controller 54 may be coupled to the lower adaptor 431 and may be connected with a portion, provided in the first area FA, of the first plate 3 through the lower adaptor 431. Each of the lower gap controller 54 and the lower adaptor 431 may be provided in plurality in the first area FA.

The upper gap controller 55 may be coupled to the upper plate 44 in an area corresponding to a second area SA. The second area SA is disposed to surround the first area FA. In this case, the first area FA may be disposed inward from the second area SA. The upper adaptor 432 may be coupled to a portion, provided in an area corresponding to the second area SA, of the upper plate 44. Therefore, the upper gap controller 55 may be coupled to the upper adaptor 432 and may be connected with a portion, provided in an area corresponding to the second area SA, of the upper plate 44 through the upper adaptor 432. Each of the upper gap controller 55 and the upper adaptor 432 may be provided in plurality in the area corresponding to the second area SA.

Here, the lower gas holes 31 formed in the first plate 3 may be arranged apart from one another by a gap D (illustrated in FIG. 2) of 8 mm to 13 mm. Therefore, even when the adaptor 43 is coupled to the first plate 3, the lower gas holes 31 may be arranged apart from one another by an equal gap D wholly. In this case, the adaptor 43 may be formed so that the lower gas holes 31 have a horizontal cross-sectional area which is less than the gap D by which the lower gas holes 31 are apart from one another. The horizontal cross-sectional area may be a cross-sectional area with respect to a horizontal direction perpendicular to the vertical direction (the Z-axis direction). For example, the adaptor 43 may be formed to have a horizontal cross-sectional width of less than 13 mm. In a case where the upper plate 44 is provided, the lower adaptor 431 may be coupled to the first plate 3. The lower adaptor 431 may be formed to have a horizontal cross-sectional area which is less than the gap D by which the lower gas holes 31 are apart from one another.

Furthermore, the upper gas holes 41 formed in the upper plate 44 may be arranged apart from one another by a gap of 8 mm to 13 mm. Therefore, even when the upper adaptor 432 is coupled to the upper plate 44, the upper gas holes 41 may be arranged apart from one another by an equal gap wholly. In this case, the upper adaptor 432 may be formed so that the upper gas holes 41 have a horizontal cross-sectional area which is less than the gap D by which the upper gas holes 41 are apart from one another. For example, the upper adaptor 432 may be formed to have a horizontal cross-sectional area of less than 13 mm.

Referring to FIGS. 1 to 8, in the substrate processing apparatus 1 according to the present inventive concept, the second plate 4 may include a plurality of protrusion electrodes 46. In this case, the first plate 3 may include a plurality of openings 33.

Each of the protrusion electrodes 46 protrude in a downward direction from the lower surface 44a of the upper plate 44. The protrusion electrodes 46 may be arranged apart from one another. The upper gas hole 41 may be formed in each of the protrusion electrodes 46. Each of the upper gas holes 41 may be formed to pass through the upper plate 44 and the protrusion electrode 46. The protrusion electrodes 46 and the upper plate 44 may be provided as one body.

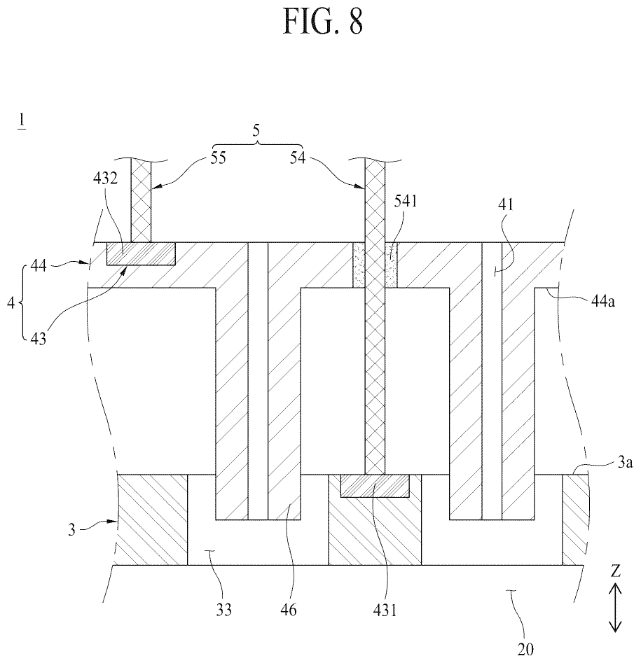

The openings 33 are formed in the first plate 3. The openings 33 may be formed at positions apart from one another to pass through the first plate 3. The openings 33 may be disposed at positions corresponding to the protrusion electrodes 46, respectively. As illustrated in FIG. 8, the protrusion electrodes 46 may protrude by a length by which the protrusion electrodes 46 are respectively inserted into the openings 33. In this case, a lower end of the protrusion electrode 46 may be disposed in the opening 33. Although not shown, the protrusion electrodes 46 may protrude by a length where each of the protrusion electrodes 46 is disposed at a position upward apart from a corresponding opening 33 of the openings 33. In this case, the lower end of the protrusion electrode 46 may be disposed between the lower surface 44a of the upper plate 44 and the upper surface 3a of the first plate 3. The lower end of the protrusion electrode 46 may be disposed on the same line as the upper surface 3a of the first plate 3. Although not shown, the protrusion electrodes 46 may protrude by a length which protrudes in a downward direction from the first plate 3 through each of the openings 33. In this case, the lower end of the protrusion electrode 46 may be disposed in the processing space 20.

Referring to FIGS. 1 to 9, the substrate processing apparatus 1 according to the present inventive concept may include a feeding unit 6.

The feeding unit 6 may be coupled to the first plate 3. When an RF power is applied to the first plate 3, the feeding unit 6 may necessarily apply the RF power to the first plate 3. In this case, the gap controller 5 may selectively apply the RF power to the first plate 3. As described above, when the RF power is applied to the first plate 3, the feeding unit 6 may function as main RF feeding, and the gap controller 5 may function as sub RF feeding. Therefore, the substrate processing apparatus 1 according to the present inventive concept may be implemented to control the number of points of the first plate 3 to which the RF power is directly applied, based on a process condition, and thus, may enhance general utilization capable of being applied to a processing process based on various process conditions. In this case, the lower gap controller 54 of the gap controllers 5 may function as sub RF feeding. The upper gap controller 55 of the gap controllers 5 may be grounded. The feeding unit 6 may be coupled to the first plate 3 at a position apart from each of the lower gap controller 54 and the upper gap controller 55.

Each of the feeding unit 6 and the gap controller 5 may be connected with the RF power feeding line 50. The feeding unit 6 may be connected with an RF power feeding line which is separately provided. The feeding unit 6 may be inserted into the upper plate 44 and may be coupled to the first plate 3. In this case, an insulation unit 61 may be disposed between the feeding unit 6 and the upper plate 44. The insulation unit 61 may insulate the feeding unit from the upper plate 44.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A substrate processing apparatus comprising:
a chamber including a lid at an upper portion thereof;
a first plate installed under the lid, a plurality of gas holes being formed in the first plate;
a second plate including a plurality of gas holes communicating with some of the plurality of gas holes of the first plate, the second plate being coupled to the first plate; and
a gap controller connected with the second plate to control a gap between the lid and the first plate,
wherein the gap controller is connected with a radio frequency (RF) power feeding line.

2. The substrate processing apparatus of claim 1, wherein a coupling groove fastened with the gap controller is formed in the second plate, and
the gap controller comprises a coupling member fastened with the second plate through the coupling groove.

3. The substrate processing apparatus of claim 1, wherein the plurality of gas holes formed in the first plate are arranged apart from one another by a gap of 8 mm to 13 mm.

4. The substrate processing apparatus of claim 1, wherein the second plate comprises an adaptor coupled to the first plate, and
the gap controller is coupled to the adaptor and is connected with the first plate through the adaptor.

5. The substrate processing apparatus of claim 4, wherein a coupling groove fastened with the gap controller is formed in the adaptor,
the gap controller comprises a coupling member fastened with the adaptor through the coupling groove, and
the coupling member rotates in a direction fastened with the adaptor to raise the adaptor.

6. The substrate processing apparatus of claim 5, wherein the gap controller comprises a supporting member supported by the lid and a connection member coupled to each of the supporting member and the coupling member, between the supporting member and the coupling member, and
the supporting member supports the first plate through the adaptor by using a supporting force supported by the lid.

7. The substrate processing apparatus of claim 4, wherein the second plate comprises an upper plate disposed on the first plate.

8. The substrate processing apparatus of claim 7, wherein each of the adaptor and the gap controller is provided in plurality,
a lower adaptor of the adaptors is coupled to the first plate,
a lower gap controller of the gap controllers is coupled to the lower adaptor and is connected with the first plate,
an upper adaptor of the adaptors is coupled to the upper plate, and
an upper gap controller of the gap controllers is coupled to the upper adaptor and is connected with the upper plate.

9. The substrate processing apparatus of claim 8, wherein the lower gap controller is disposed more inward than the upper gap controller.

10. The substrate processing apparatus of claim 8, wherein the lower gap controller is fastened with the lower adaptor and rotates in a direction fastened with the lower adaptor to raise the lower adaptor.

11. The substrate processing apparatus of claim 8, wherein the second plate comprises a plurality of protrusion electrodes protruding in a downward direction from a lower surface of the upper plate, and
a plurality of openings into which the protrusion electrodes are inserted are formed in the first plate.

12. The substrate processing apparatus of claim 4, wherein an inserting groove into which the adaptor is inserted is formed in an upper surface of the first plate, and
the adaptor is inserted into the inserting groove so that an upper surface thereof is disposed at a height which is higher than the upper surface of the first plate.

13. The substrate processing apparatus of claim 4, wherein an inserting groove into which the adaptor is inserted is formed in an upper surface of the first plate, and
the adaptor is inserted into the inserting groove so that an upper surface thereof is disposed at the same height as the upper surface of the first plate.

14. The substrate processing apparatus of claim 4, wherein the adaptor is coupled to an upper surface of the first plate to protrude in an upward direction from the upper surface of the first plate.

15. The substrate processing apparatus of claim 1, further comprising a feeding unit coupled to the first plate,
wherein, when an RF power is applied to the first plate, the feeding unit necessarily applies the RF power to the first plate and the gap controller selectively applies the RF power to the first plate.
